(19) United States
(12) Patent Application Publication
(10) Pub. No.: US 2022/0201230 A1
(43) Pub. Date: Jun. 23, 2022

(54) SENSING APPARATUS AND SENSING METHOD THEREOF

(71) Applicant: Egis Technology Inc., Hsinchu City (TW)

(72) Inventor: Wan-Jung Lo, Hsinchu City (TW)

(73) Assignee: Egis Technology Inc., Hsinchu City (TW)

(21) Appl. No.: 17/494,836

(22) Filed: Oct. 6, 2021

Related U.S. Application Data
(60) Provisional application No. 63/129,487, filed on Dec. 22, 2020.

(30) Foreign Application Priority Data
Aug. 19, 2021 (CN) 202110955197.4

(51) Int. Cl. H04N 5/369

(52) U.S. Cl. CPC H04N 5/3698

(57) ABSTRACT

A sensing apparatus and a sensing method of the sensing apparatus are provided. A charging control circuit of the sensing apparatus adjusts a value of a sensing current to increase a charging rate of the sensing current for charging an output capacitor and shorten time for an output sensing voltage to reach a stable state.

### CROSS-REFERENCE TO RELATED APPLICATION

This application claims the priority benefit of U.S. provisional application Ser. No. 63/129,487, filed on Dec. 22, 2020, and China application serial no. 202110955197.4, filed on Aug. 19, 2021. The entirety of each of the above-mentioned patent applications is hereby incorporated by reference herein and made a part of this specification.

### BACKGROUND

### Technical Field

The disclosure relates to an electronic apparatus; more particularly, the disclosure relates to a sensing apparatus and a sensing method thereof.

### Description of Related Art

A common image sensing apparatus may include a sensing pixel array constituted by a plurality of sensing pixels, and each sensing pixel may, for instance, convert incidence light to a sensing signal. By analyzing the sensing signal provided by each sensing pixel, an image sensed by the sensing pixel array may be obtained. An image sensing technology can usually be applied to personal safes, door locks, consumer electronic devices (e.g., personal computers, mobile phones, tablet computers), and so on, and sensing results are employed for identification to improve security. With the maturity of related technologies, requirements for image sensing quality become higher and higher. Therefore, how to improve the sensing efficiency without affecting the sensing quality of the image sensing apparatus is an important topic for people in the pertinent field.

### SUMMARY

The disclosure provides a sensing apparatus and a sensing method thereof, which may effectively improve sensing efficiency of the sensing apparatus.

In an embodiment of the disclosure, a sensing apparatus includes a sensing unit, an output capacitor, and a charging control circuit. The sensing unit performs an image sensing operation to generate a sensing current. The output capacitor is coupled between an output end of the sensing unit and a reference voltage and generates an output sensing voltage in response to the sensing current. The charging control circuit is coupled to the sensing unit and adjusts a value of the sensing current value to increase a charging rate of the sensing current for charging the output capacitor and shorten time for the output sensing voltage to reach a stable state.

In another embodiment of the disclosure, a sensing method of a sensing apparatus is provided. The sensing apparatus includes a sensing unit, an output capacitor, and a charging control circuit, the output capacitor is coupled between an output end of the sensing unit and a reference voltage, and the output capacitor generates an output sensing voltage in response to the sensing current. The sensing method of the sensing apparatus includes following steps. The sensing unit is controlled to perform an image sensing operation to generate a sensing current. A value of the sensing current value is adjusted to increase a charging rate of the sensing current for charging the output capacitor and shorten time for the output sensing voltage to reach a stable state.

In view of the above, the charging control circuit provided in one or more embodiments of the disclosure may adjust the value of the sensing current to increase the charging rate of the sensing current for charging the output capacitor, shorten the time for the output sensing voltage to reach the stable state, and further effectively improve the sensing efficiency of the sensing apparatus.

To make the above more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic view of a sensing apparatus according to an embodiment of the disclosure.

FIG. 2 is a schematic view of a sensing apparatus according to another embodiment of the disclosure.

FIG. 3 is a schematic view of a switch control signal and an output sensing voltage according to an embodiment of the disclosure.

FIG. 4 is a flowchart of a sensing method of a sensing apparatus according to an embodiment of the disclosure.

FIG. 5 is a flowchart of a sensing method of a sensing apparatus according to another embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

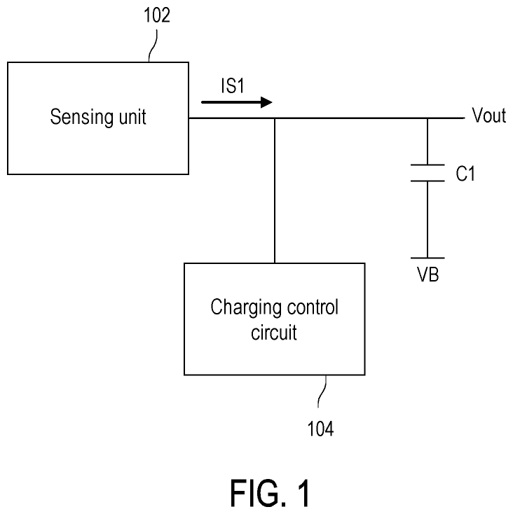

FIG. 1 is a schematic view of a sensing apparatus according to an embodiment of the disclosure. With reference to FIG. 1, a sensing apparatus includes a sensing unit 102, an output capacitor C1, and a charging control circuit 104. The output capacitor C1 is coupled between an output end of the sensing unit 102 and a reference voltage VB, and the charging control circuit 104 is coupled to the sensing unit 102. Here, the reference voltage VB may be, for instance, a ground voltage, which should however not be construed as a limitation in the disclosure. The sensing unit 102 may perform an image sensing operation (e.g., fingerprint sensing, which should however not be construed as a limitation in the disclosure) and generate a corresponding sensing current IS1. The sensing current IS1 may charge the output capacitor C1, so that the output capacitor C1 generates an output sensing voltage Vout in response to the sensing current IS1 for image processing by a back-end processing circuit. The charging control circuit 104 may adjust a current value of the sensing current IS1 to adjust a charging rate of the sensing current IS1 to the output capacitor C1 and shorten time for the output sensing voltage Vout to reach a stable state. For instance, the charging control circuit 104 may adjust the value of the sensing current IS1 by increasing the value of the sensing current first and then decreasing the value of the sensing current. Namely, the sensing current IS1 is firstly raised to a relatively large value, and before the output sensing voltage Vout reaches the stable state, the sensing current US1 is adjusted to have a relatively small value until the output sensing voltage Vout reaches the stable state.

By first raising the sensing current IS1 to a relatively large current value, the charging rate of charging the output capacitor C1 may be expedited, and before the output sensing voltage Vout reaches the stable state, the sensing current US1 is adjusted to have a relatively small current value, which allows the output capacitor C1 to be accurately charged and reduces power consumption. Therefore, through the adjustment of the sensing current by the charging control circuit 104, the time for the output sensing voltage to reach the stable state may be shortened without affecting the sensing quality of the sensing apparatus, and the sensing efficiency of the sensing apparatus may be effectively improved.

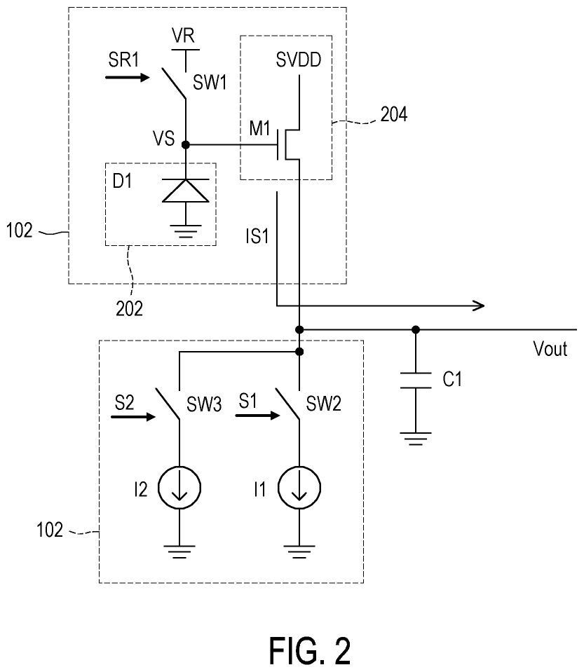

FIG. 2 is a schematic view of a sensing apparatus according to another embodiment of the disclosure. To be specific, an implementation manner of the sensing unit 102 and the charging control circuit 104 may be, for instance, as shown in FIG. 2. In FIG. 2, the sensing unit 102 may include a reset switch SW1, a photoelectric converting unit 202, and a buffer amplifier circuit 204, and the charging control circuit 104 may include switches SW2 and SW3 and current sources I1 and I2. Here, the reset switch SW1 is coupled between the reset voltage VR and the photoelectric converting unit 202, and the buffer amplifier circuit 204 is coupled to the photoelectric converting unit 202. In this embodiment, the photoelectric converting unit 202 is implemented by a photoelectric diode D1, and the buffer amplifier circuit 204 is implemented by a transistor M1, which should however not be construed as a limitation in the disclosure. A cathode and an anode of the photoelectric diode D1 are respectively coupled to the reset switch SW1 and the ground voltage, the transistor M1 is coupled between a power supply voltage SVDD and the switch SW2, and a control end of the transistor M1 is coupled to the cathode of the photoelectric diode D1. The switch SW2 and the current source I1 are serially connected between the transistor M1 and the ground voltage, and the switch SW3 and the current source 12 are serially connected between the transistor M1 and the ground voltage.

The reset switch SW1 may be turned on under the control of a reset control signal SR1 during a reset period, thereby resetting a gate voltage of the transistor M1. During a sensing period of the sensing apparatus, the reset switch SW1 is controlled by the reset control signal SR1 and is being turned off. At this time, the photoelectric diode D1 may convert an optical signal including image information to an electrical signal, and a corresponding sensing voltage VS1 may be generated at a gate of the transistor M1. The transistor M1 may respond to the electrical signal provided by the photoelectric diode D1; that is, the sensing voltage VS1 at the gate generates the sensing current IS1 to charge the output capacitor C1.

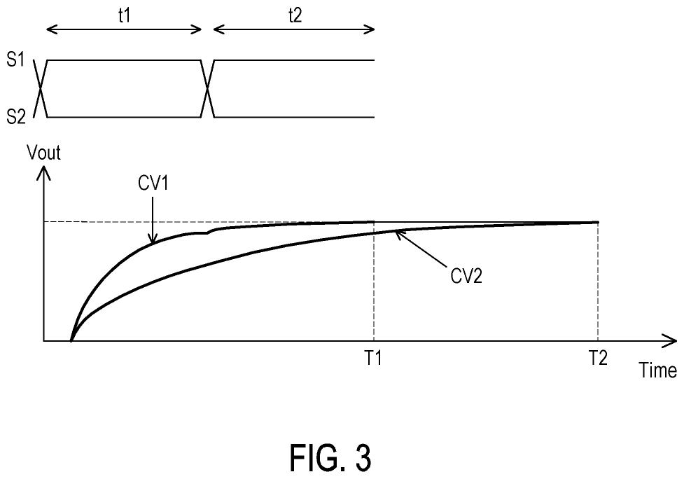

The current sources I1 and 12 in the charging control circuit 104 may respectively provide a first constant current and a second constant current, wherein the first constant current is greater than the second constant current. In the sensing period of the sensing apparatus, as shown in FIG. 3, the charging control circuit 104 may have the output capacitor C1 enter a charging period t1 and a charging period t2 successively. During the charging period t1, the switch SW2 is controlled by a switch control signal S1 and is being turned on, and the switch SW3 is controlled by a switch control signal S2 and is being turned off, which may increase the value of sensing current IS1 and significantly increase a speed of charging the output capacitor C1. During the charging period t2, the switch SW2 is controlled by the switch control signal S1 and is being turned off, and the switch SW3 is controlled by the switch control signal S2 and is being turned on, so as to reduce the value of the sensing current IS1 and charge the output capacitor C1 in a relatively linear and accurate manner.

As shown in FIG. 3, time T2 is required to charge the output capacitor C1 and have the output sensing voltage Vout reach the stable state (as shown by a curve CV2) if the sensing current IS1 with an unadjusted current value is applied to charge the output capacitor C1. By contrast, according to this embodiment, if the sensing current IS1 with the adjusted current value is applied to charge the output capacitor C1, it only takes the time T1 to have the output sensing voltage Vout reach the stable state (as shown by a curve CV1, i.e., reaching a stable voltage).

In this embodiment, during the charging period t1, note that the switch SW2 is controlled by the switch controlling signal S1 and is being turned on, and the switch SW3 is controlled by the switch controlling signal S2 and is being turned off; however, in other embodiments, the switches SW2 and SW3 may also be in an on state to further expedite the speed of charging the output capacitor C1 and improve the sensing efficiency of the sensing apparatus. In addition, according to the embodiment depicted in FIG. 2, a photo-sensing device is applied to implement the sensing unit 102, which should however not be construed as a limitation in the disclosure. The sensing unit 102 may also be implemented, for instance, by a capacitive sensor or in another manner.

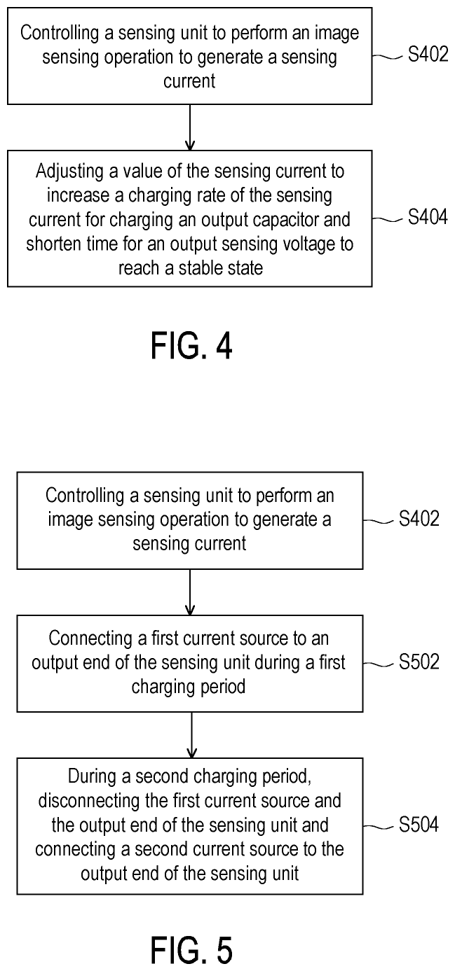

FIG. 4 is a flowchart of a sensing method of a sensing apparatus according to an embodiment of the disclosure. Here, the sensing apparatus includes a sensing unit, an output capacitor, and a charging control circuit, the output capacitor is coupled between an output end of the sensing unit and a reference voltage, and the output capacitor generates an output sensing voltage in response to the sensing current. As provided in the previous embodiments, the sensing method of the sensing apparatus may include at least following steps. First, a sensing unit is controlled to perform an image sensing operation to generate a sensing current (step S402). Next, a value of the sensing current is adjusted to increase a charging rate of the sensing current for charging an output capacitor and shorten time for the output sensing voltage to reach a stable state (step S404). Here, a method of adjusting the value of the sensing current may be, for instance, carried out by increasing the value of the sensing current first and then decreasing the value of the sensing current, which should however not be construed as a limitation in the disclosure.

Particularly, the sensing unit and the charging control circuit may be, for instance, implemented in the manner provided in the embodiment depicted in FIG. 2, and therefore no further explanation is provided hereinafter. On the condition that the sensing unit and the charging control circuit are implemented in the manner provided in the embodiment depicted in FIG. 2, the sensing method of the sensing apparatus may be as shown in FIG. 5; after step S402, a first current source is connected to an output end of the sensing unit during a first charging period (step S502); during a second charging period, the first current source and the output end of the sensing unit are disconnected, and the second current source is connected to the output end of the sensing unit (step S504). Here, the first current source serves to provide a first constant current, the second current source serves to provide a second constant current, and the first constant current is greater than the second constant current. As such, the value of the sensing current may be changed in the manner of increasing the value of the sensing current first and then decreasing the value of the sensing current, and the time for the output sensing voltage to reach the stable may be shortened without affecting the sensing quality of the sensing apparatus, so as to effectively improve the sensing efficiency of the sensing apparatus.

To sum up, the charging control circuit provided in one or more embodiments of the disclosure may adjust the value of the sensing current to increase the charging rate of the sensing current for charging the output capacitor, shorten the time for the output sensing voltage to reach the stable state, and further effectively improve the sensing efficiency of the sensing apparatus.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A sensing apparatus, comprising:
a sensing unit, performing an image sensing operation to generate a sensing current;
an output capacitor, coupled between an output end of the sensing unit and a reference voltage and generating an output sensing voltage in response to the sensing current; and
a charging control circuit, coupled to the sensing unit and adjusting a value of the sensing current to increase a charging rate of the sensing current to charge the output capacitor and shorten time for the output sensing voltage to reach a stable state.

2. The sensing apparatus according to claim 1, wherein the charging control circuit adjusts the value of the sensing current by increasing the value of the sensing current first and then decreasing the value of the sensing current.

3. The sensing apparatus according to claim 1, wherein the charging control circuit comprises:
a first switch;
a first current source, the first current source and the first switch being serially connected between the output end of the sensing unit and the reference voltage, the first current source providing a first constant current;
a second switch;
a second current source, the second current source and the second switch being serially connected between the output end of the sensing unit and the reference voltage, the second current source providing a second constant current, the first switch and the output capacitor enter a first charging period and a second charging period successively, wherein in the first charging period, the first switch is being turned on and the second switch is being turned off, and in the second charging period, the first switch is being turned off and the second switch is being turned on.

4. The sensing apparatus according to claim 3, wherein the first constant current is greater than the second constant current.

5. The sensing apparatus according to claim 1, wherein the sensing unit comprises:
a reset switch, one end of the reset switch being coupled to a reset voltage, wherein the reset switch is being turned on in a reset period and is being turned off in a sensing period;
a photoelectric converting unit, coupled to the other end of the reset switch and converting an optical signal including image information to an electrical signal; and
a buffer amplifier circuit, coupled to the photoelectric converting unit and generating the sensing current in response to the electrical signal.

6. The sensing apparatus according to claim 5, wherein the photoelectric converting unit comprises:
a photoelectric diode whose cathode and anode are respectively coupled to the other end of the reset switch and the reference voltage.

7. The sensing apparatus according to claim 5, wherein the buffer amplifier circuit comprises:
a transistor, coupled between a power supply voltage and an output end of the buffer amplifier circuit, a control end of the transistor being coupled to an output end of the photoelectric converting unit.

8. A sensing method of a sensing apparatus, the sensing apparatus comprising a sensing unit, an output capacitor, and a charging control circuit, the output capacitor being coupled between an output end of the sensing unit and a reference voltage, the output capacitor generating an output sensing voltage in response to a sensing current, the sensing method of the sensing apparatus comprising:
controlling the sensing unit to perform an image sensing operation to generate the sensing current;
adjusting a value of the sensing current to increase a charging rate of the sensing current to charge the output capacitor and shorten time for the output sensing voltage to reach a stable state.

9. The sensing method according to claim 8, comprising:
adjusting the value of the sensing current by increasing the value of the sensing current first and then decreasing the value of the sensing current.

10. The sensing method according to claim 8, wherein the output capacitor enters a first charging period and a second charging period successively, and the sensing method of the sensing apparatus comprises:
connecting a first current source to an output end of the sensing unit during the first charging period; and
disconnecting the first current source and the output end of the sensing unit during the second charging period and connecting a second current source to the output end of the sensing unit, wherein the first current source provides a first constant current, and the second current source provides a second constant current.

11. The sensing method according to claim 10, wherein the first constant current is greater than the second constant current.

12. The sensing method according to claim 8, wherein the sensing unit comprises:
a reset switch, one end of the reset switch being coupled to a reset voltage, wherein the reset switch is being turned on in a reset period and is being turned off in a sensing period;
a photoelectric converting unit, coupled between the other end of the reset switch and converting an optical signal including image information to an electrical signal; and
a buffer amplifier circuit, coupled to the photoelectric converting unit and generating the sensing current in response to the electrical signal.

13. The sensing method according to claim 12, wherein the photoelectric converting unit comprises:
a photoelectric diode whose cathode and anode are respectively coupled to the other end of the reset switch and the reference voltage.

14. The sensing method according to claim 12, wherein the buffer amplifier circuit comprises:
a transistor, coupled between a power supply voltage and an output end of the buffer amplifier circuit, a control end of the transistor being coupled to an output end of the photoelectric converting unit.
